(19) United States
(12) Patent Application Publication
(10) Pub. No.: US 2022/0069545 A1
(43) Pub. Date: Mar. 3, 2022

(54) Controlling optical pulse shape of a laser diode

(71) Applicant: Apple Inc., Cupertino, CA (US)

(72) Inventors: Harish Venkataraman, Half Moon Bay, CA (US); Chinhan Lin, Cupertino, CA (US); Fei Tan, Santa Clara, CA (US); Ido Luft, Sunnyvale, CA (US); Moshe Laifenfeld, Haifa (IL); Susan A. Thompson, Half Moon Bay, CA (US)

(21) Appl. No.: 17/378,711

(22) Filed: Jul. 18, 2021

Related U.S. Application Data
(60) Provisional application No. 63/070,295, filed on Aug. 26, 2020.

(51) Int. Cl. H01S 5/042; H03K 17/687

(52) U.S. Cl. CPC H01S 5/0428; H01S 5/183; H03K 17/6871

(57) ABSTRACT

An optoelectronic device includes a laser diode, a driver and a reverse-bias circuit. The laser diode has a first terminal and a second terminal. The driver is coupled to drive current pulses through the laser diode between the first and second terminals. The reverse-bias circuit is configured to reverse-bias the laser diode during time intervals derived from the current pulses.

### CROSS-REFERENCE TO RELATED APPLICATION

This application claims the benefit of U.S. Provisional Patent Application 63/070,295, filed Aug. 26, 2020, which is incorporated herein by reference.

### FIELD OF THE INVENTION

The present invention relates generally to optoelectronic devices, such as vertical-cavity surface-emitting lasers (VCSELs), and particularly to circuits and methods for driving such devices to generate short optical pulses.

### BACKGROUND

Various schemes for driving VCSELs and other pulsed solid-state emitters are known in the art.

### SUMMARY

An embodiment of the present invention that is described herein provides an optoelectronic device including a laser diode, a driver and a reverse-bias circuit. The laser diode has a first terminal and a second terminal. The driver is coupled to drive current pulses through the laser diode between the first and second terminals. The reverse-bias circuit is configured to reverse-bias the laser diode during time intervals derived from the current pulses.

In some embodiments, the laser diode includes a vertical-cavity surface-emitting laser (VCSEL). In disclosed embodiments, the reverse-bias circuit is configured to reverse-bias the laser diode at a first time-delay after start times of the current pulses, and to stop reverse-biasing the laser diode at a second time-delay after end times of the current pulses. In an example embodiment, by reverse-biasing the laser diode, the reverse-bias circuit is configured to set a fall time of 40 db of an emitted optical energy of the laser diode to less than 2 nano-seconds.

In some embodiments, the driver includes a unidirectional current source configured to generate the current pulses, and the reverse-bias circuit includes an additional power source configured to generate power for reverse-biasing the laser diode. In an embodiment, the additional power source includes a charge-pump circuit. In another embodiment, the additional power source includes a resistance, across which a voltage drop develops as a result of the current pulses. In yet another embodiment, the driver is configured to generate the current pulses from a first supply voltage, and wherein the reverse-bias circuit is configured to reverse-bias the laser diode using a second supply voltage, higher than the first supply voltage.

There is additionally provided, in accordance with an embodiment of the present invention, a method including driving current pulses through a laser diode. The laser diode is reverse-biased during time intervals derived from the current pulses.

The present invention will be more fully understood from the following detailed description of the embodiments thereof, taken together with the drawings in which:

### BRIEF DESCRIPTION OF THE DRAWINGS

FIG. 1 is a schematic circuit diagram showing an optoelectronic device, in accordance with an embodiment of the present invention;

FIG. 2 is a schematic circuit diagram showing an optoelectronic device, including a driver circuit, in accordance with an embodiment of the present invention;

FIG. 3 is a diagram that schematically illustrates waveforms of the driver circuit, in accordance with an embodiment of the present invention;

FIG. 4 is a diagram that schematically illustrates curves of the light pulse emitted by a VCSEL, in accordance with an embodiment of the present invention;

FIG. 5 is a schematic circuit diagram showing an optoelectronic device, including a driver circuit, in accordance with another embodiment of the present invention; and

FIG. 6 is a schematic circuit diagram showing an optoelectronic device, including a driver circuit, in accordance with yet another embodiment of the present invention.

### DETAILED DESCRIPTION OF EMBODIMENTS

Semiconductor laser diodes, and particularly VCSELs, are used in a variety of applications to generate short, high-power optical pulses. For example, in depth mapping based on time of flight (ToF) measurement, one or more VCSELs direct optical pulses toward a target scene, and a receiver senses the times of arrival of photons reflected back from points in the scene in order to create the depth map. The temporal resolution of the ToF measurements, and hence the depth resolution of the map, are limited by the temporal duration of the optical pulses emitted by the VCSELs. For this reason, the VCSELs are typically driven to emit pulses having a duration on the order of a few nanoseconds (e.g., 2 ns).

Various schemes can be used for shortening the duration of pulses emitted by VCSELs. It is possible, for example, to form a short circuit between the anode terminal and the cathode terminal of the VCSEL, thus discharging residual charge and terminating optical emission. Such schemes are less suitable since they do not deplete the residual charge form the quantum wells.

To achieve high peak current with low average power consumption, these sorts of portable devices may use a unidirectional current source, which quickly forces current through the VCSEL in one direction, and then quickly turns off the current until the next pulse. (The term “current source,” as used in the context of the present description and in the claims, includes sources of both positive and negative currents, which are commonly referred to respectively as current sources and current sinks.) When this sort of scheme is used, however, residual charge remains at the junction (active region made by quantum wells and barrier layers) of the VCSEL even after the current source has been shut off. This residual charge causes the VCSEL to continue emitting optical radiation, with the result that the optical pulse has a long “tail” following the end of the current pulse. When the VCSEL is used in a ToF-based depth mapper, this lengthening of the optical pulses can have a deleterious effect on depth mapping performance, as explained above.

One way to shorten the above-described “tail” is to rapidly discharge the laser diode at the conclusion of the current pulse using a discharge switch that forms a short circuit between the anode terminal and the cathode terminal of the laser diode. This technique shortens the “tail”, but a residual tail remains, which may limit the accuracy of ToF measurements.

Embodiments of the present invention that are described herein rapidly discharge the laser diode at the conclusion of the current pulse by reverse biasing the laser diode, e.g., at a voltage of −0.5V. As simulated, if the laser diode is shorted at the conclusion of the current pulse, the light power drops by 40 db (decibel) in 2.5 ns (nanosecond), whereas, in embodiment according to the present invention, reverse-biasing the laser diode causes the light power to drop by 40 db in 1.5 ns.

In an embodiment, the reverse biasing is achieved by applying a voltage level to the cathode that is greater than the voltage level applied to the anode by 0.5V or more. In another embodiment, a charge-pump circuit generates the power source used to reverse-bias the diode, and in yet another embodiment the reverse bias is generated by voltage drops generated by the VCSEL current, when passing through resistances (the intrinsic resistance of the path, or a combination of the intrinsic resistance and a dedicated resistor).

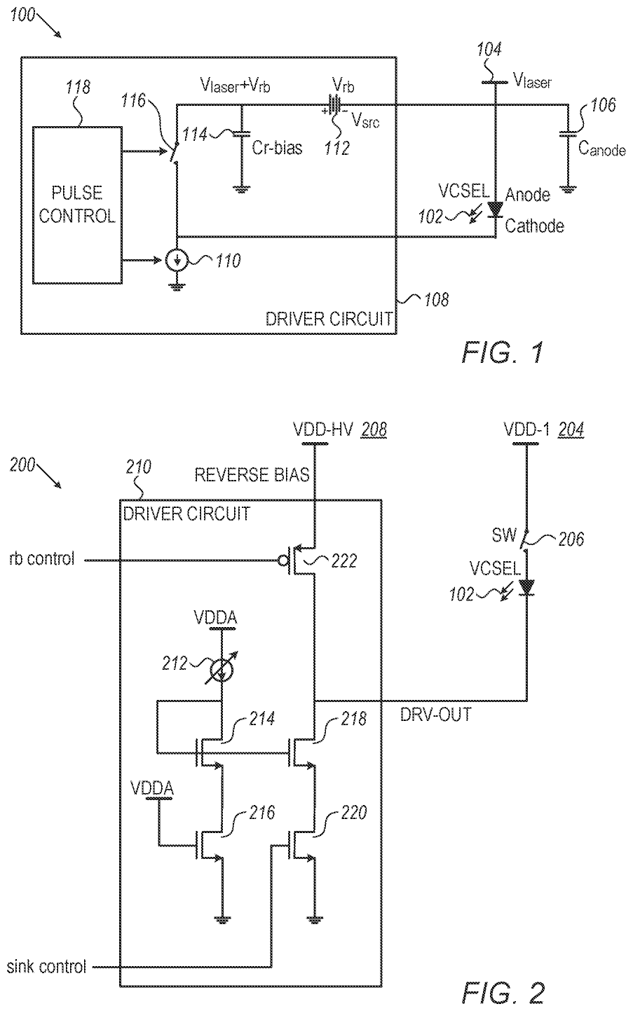

FIG. 1 is a schematic circuit diagram 100 showing an optoelectronic device, in accordance with an embodiment of the present invention. According to the example embodiment illustrated in FIG. 1, The optoelectronic device comprises a VCSEL diode 102; the present invention, however, is not limited to VCSELs; any other suitable optoelectronic devices may be used in alternative embodiments.

The anode terminal of the VCSEL is connected to a voltage source (Vₗₐₛₑᵣ) 104, which charges a capacitor C_{anode} 106 between laser pulses (capacitor C_{anode} 106 may be needed if the instantaneous current through VCSEL 102 at any time is beyond the drive capability of voltage source 104).

A Driver Circuit 108 is operable to sink short, intense, unidirectional current pulses, from voltage source 104 and capacitor C_{anode} 106, through VCSEL 102 (from VCSEL anode to VCSEL cathode), thus causing the VCSEL to emit light pulses. (The driver circuit is thus unidirectional, with low power consumption and heat dissipation, in contrast to bidirectional driver circuits based on push-pull arrangements.)

Driver Circuit 108 comprises a switchable current source 110, a reverse bias voltage source V_{src} 112, a decoupling capacitor C_{r-bias} 114, a switch 116 (e.g., a suitable transistor) and a Pulse-Control circuit 118. Voltage source V_{src} 112 adds a V_{rb} voltage potential to Vₗₐₛₑᵣ, charging capacitor C_{r-bias} 114 to Vₗₐₛₑᵣ+V_{rb}. In embodiments that are described herein, V_{rb} may be generated by a charge pump, by voltage drop over a resistive path or by a separate voltage supply; in other embodiments any other suitable circuits may be used to generate Vₗₐₛₑᵣ+V_{rb}. In embodiments, V_{rb} is typically 0.5V.

To drive VCSEL 102, Pulse-Control 118 controls current-source 110 to sink a current pulse from the cathode of the VCSEL, which generates a corresponding light pulse. When the current pulse ends, the light pulse may not stop immediately but, rather, light intensity may gradually decrease. Such gradual decrease may reduce the accuracy of ToF measurements.

According to the example embodiment illustrated in FIG. 1, when (or shortly before) the current pulse that current-source 110 sinks ends, the pulse control circuit activates switch 116, which connects the cathode of VCSEL 102 to the Vₗₐₛₑᵣ+V_{rb} voltage on C_{r-bias} 114, thereby raising the potential of the cathode to a voltage level higher than the anode by V_{rb}. In embodiments, this reverse biasing of VCSEL rapidly terminates the light pulse, enabling more accurate ToF measurements.

Thus, according to the example embodiment illustrated in FIG. 1, reverse biasing of the VCSEL at or in close proximity to the time at which the driving current pulse ends shortens the trailing edge of the light pulse emitted from the VCSEL, increasing the accuracy of ToF (and hence, the accuracy of distance measurements).

As would be appreciated, the structure of driver circuit 108 described above is cited by way of example. Driver circuits in accordance with the disclosed techniques are not limited to the description hereinabove. In alternative embodiments, for example, the polarities of VCSEL 102, current source 110 and V_{src} 112 may be reversed (e.g., current source 110 will source current pulses into the anode of VCSEL 102, the cathode of the VCSEL will be coupled to a zero potential, and the voltage on capacitor C_{r-bias} 114 will be negative). In an embodiment, C_{anode} 106 and/or C_{r-bias} 114 may comprise a plurality of capacitors, of the same or of different types. In some embodiments, the anode of VCSEL 102 is coupled to voltage source 104 through an additional switch, for example, to allow an x-y selection of a single VCSEL from an array of VCSELs.

FIG. 2 is a schematic circuit diagram 200 showing an optoelectronic device, including a driver circuit 210, in accordance with an embodiment of the present invention. The anode of VCSEL 102 (FIG. 1) is coupled to a voltage source VDD-1 204 (typically a few volts through a switch 206 (switch 206 is typically a FET or a bipolar transistor). A VDD-HV power voltage source 208 supplies a voltage level that is higher than VDD-1 by typically 0.5V (other voltages may be used in alternative embodiments). This voltage level will be used to reverse-bias VCSEL 102 when the light pulse is to be sharply terminated. (Decoupling capacitors such as C_{r-bias} 112 and C_{anode} 106 (FIG. 1) are not shown, for clarity.)

A Driver Circuit 210 is configured to drive VCSEL 102 with current pulses, and to terminate the current pulses by reverse-biasing the VCSEL. The driver circuit comprises an adjustable reference current source 212; an N-MOS transistor 214, which is configured as a forward-biased diode; an N-MOS transistor 216, whose gate is coupled to a VDDA voltage level (VDDA is set so that transistor 216 is at the saturation region e.g., 5V; in some embodiments, VDDA is the internal digital voltage supply); an N-MOS transistor 218, which is configured as a current mirror of transistor 214; and, an N-MOS transistor 220, which is configured to allow current pulses through transistor 218 when a Sink-Control input is at a Logic-High level.

The adjustable reference current source 212 is configured to sink an adjustable current from a VDDA source (In some embodiments, the adjustable reference current source is coupled to a Digital-to-Analog Converter (DAC), to allow digital control of the sourced current).

As would be appreciated, transistor pairs 214, 216 and 218, 220 are configured as a current mirror; when the gate of transistor 220 is at a logic-high level, the current through transistors 218, 220 will equal the current through the adjustable current source 212. In some embodiments, transistors 214 and 218 have similar geometries and hence similar electrical parameters. In other embodiments, the ratio between the channel widths of transistors 214 and 218 is preset (when the circuit is designed), and thus the current through transistors 218, 220 is a known multiple of the current sourced by the adjustable current source.

Thus, when the sink-control input is at logic-high, Driver-Circuit 210 sinks an adjustable current through VCSEL 102, which, in response, emits light.

The Driver Circuit further comprises a P-MOS transistor 222, which is configured to connect the cathode of VCSEL 102 to the reverse bias input of the driver circuit (coupled to VDD-HD 208) when an rb-control input, coupled to the gate of transistor 222, is at a low voltage (e.g., 0 V). The rb-control input is pulsed low when (or a short time before) the sink control pulse ends. As a result of the reverse bias, the light emitted by VCSEL 102 rapidly turns off.

In summary, according to the example embodiment illustrated in FIG. 2, Driver Circuit 210 is controlled by a Sink Control input that sinks an adjustable-current pulse through VCSEL 102, and an rb-control input, which is operable to reverse bias the VCSEL when or near the time that the current pulse ends. Thus, the light pulses emitted by the VCSEL have a fast turn-off time.

As would be appreciated, the structure of driver circuit 210 described above is cited by way of example. driver circuits in accordance with the disclosed techniques are not limited to the description hereinabove. In alternative embodiments, for example, some or all of N-MOS transistors 214, 216, 218, 220 and P-MOS transistor 222 may be replaced by any other suitable electronic devices, including but not limited to J-FET transistors, bipolar transistors, SCRs and thyristors.

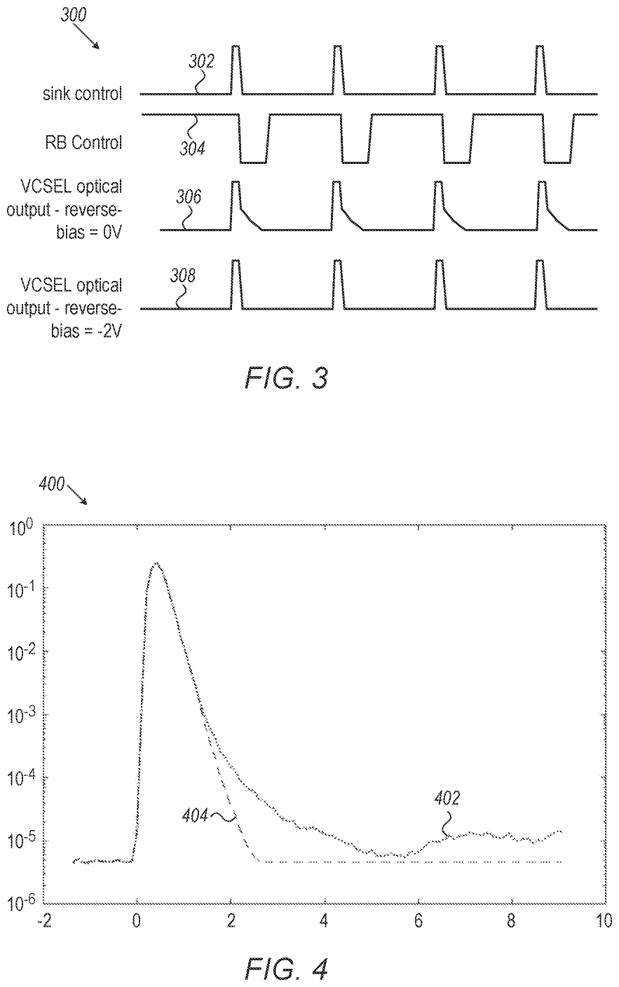

FIG. 3 is a diagram 300 that schematically illustrates waveforms of the driver circuit, in accordance with an embodiment of the present invention. A Sink-Control waveform 302 illustrates the pulses that are applied to the gate of transistor 220 and an RB Control waveform 304 illustrates the negative pulses applied to the gate of transistor 222 (both transistors were described with reference to FIG. 2). The sink-control input controls the current pulses through the VCSEL. When a pulse in sink-control starts, rb-control input is at a logic-high, and transistor 222 is off. Shortly prior to the termination of the current pulse, the rb-control input is pulsed (that is—transitions to low level, and then return to high level). The rb-control pulse may remain low until after the pulse of pulse-control 302 is at low.

As explained above the negative pulse on the rb-control input reverse-biases the VCSEL, causing a fast termination of the current pulse through the VCSEL and rapid termination of the light pulse.

A waveform 306 illustrates the optical output of the VCSEL when the reverse bias voltage is 0V (e.g., when the RB control pulse is on (low), the cathode and the anode of the VCSEL are shorted to each other). The current starts to fall at a sharp slope, but at some point the slope gentles, and a current “tail” (as well as a “tail” in the emitted light) occurs.

According to embodiments of the present invention, for shorter “tails”, the reverse bias voltage is negative. A waveform 308 illustrates the optical output of the VCSEL when the reverse bias voltage is −2V. As can be seen, the “tail” is considerably shorter than the tail of waveform 306.

As would be appreciated, the waveforms illustrated in FIG. 3 are cited by way of example, for the purpose of conceptual clarity. As such, diagram 300 does not display horizontal (time) or vertical (voltage and current) units. The ratios between time delays and the voltages may be considerably different than the illustrated ratios.

FIG. 4 is a diagram 400 that schematically illustrates simulated curves of the light pulse emitted by VCSEL 102, in accordance with an embodiment of the present invention. The horizontal axis in FIG. 4 is time, measured in nano-second, whereas the vertical axis depicts the relative power of the emitted light in a logarithmic scale.

The power of the emitted light as a function of time is illustrated in a curve 402 for the case wherein V_{rb}=0V, and in a curve 404 for V_{rb}=−2V. Curves 402 and 404 were extracted using circuit simulations. As can be seen, curves 402 and 404 track each other until they reach a power level of approximately −30 db. From that point on, curve 404 continues to fall sharply, whereas curve 402 exhibits a substantial “tail”.

Further embodiments according to the present invention that will be disclosed herein comprise the same Driver Circuit 210 of the embodiment illustrated in FIG. 2. The difference between the embodiments is the technique in which the reverse bias voltage is generated.

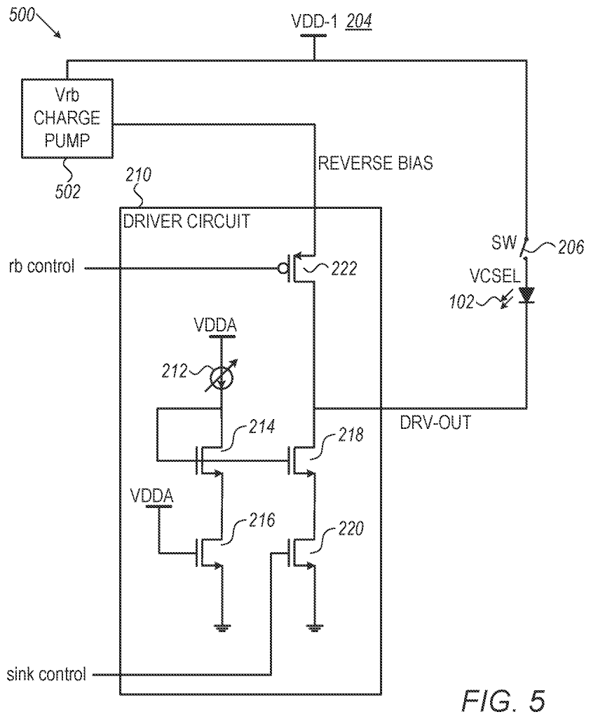

FIG. 5 is a schematic circuit diagram 500 showing an optoelectronic device, including a driver circuit 210, in accordance with another embodiment of the present invention. A Driver Circuit 210, identical to the Driver Circuit of the embodiment illustrated in FIG. 2, drives current pulses from VDD-1 204 through VCSEL 102, and couples the cathode of VCSEL 102 to a reverse bias when or shortly before the current pulse terminated. A Charge-Pump 502 generates a V_{rb} potential, greater than VDD-1 by V_{rb}. Thus, when rb-control input is active (low) and switch 206 is on, the cathode of VCSEL 102 is reversed-biased relative to the anode by V_{rb} (ignoring any voltage drops, e.g., on Switch 206).

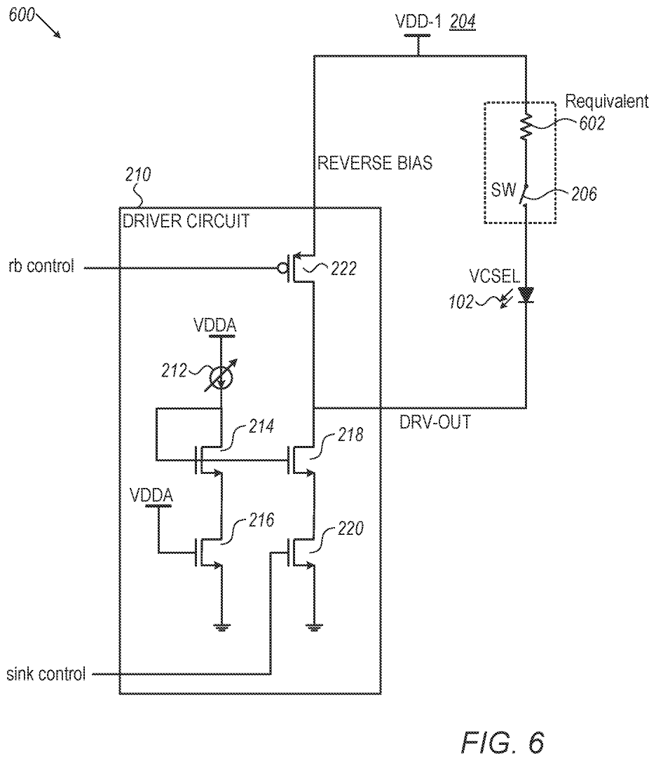

FIG. 6 is a schematic circuit diagram 600 showing an optoelectronic device, including a driver circuit 210, in accordance with yet another embodiment of the present invention. A Driver Circuit 210, identical to the Driver Circuit of the embodiment illustrated in FIG. 2, drives current pulses from VDD-1 204 through VCSEL 102, and couples the cathode of VCSEL 102 to a reverse bias when or shortly before the current pulse terminates. According to the example embodiment illustrated in FIG. 6, V_{rb} is generated by a voltage drop on a resistance R_{equivaient} 602 between VDD-1 204 and the anode of VCSEL 102. When switch 206 turns off, the intrinsic capacitance of VCSEL 102 keeps the anode voltage below VDD1 for a time duration sufficient for VCSEL fast turn off. In some embodiment, the intrinsic resistance of switch 206 and the conductors may suffice; in other embodiment, an additional resistor may be required.

As would be appreciated, the embodiments disclosed in FIGS. 1, 2, 5 and 6 above and the corresponding V_{rb} generation techniques are cited by way of example. Other V_{rb} generation techniques may be used in alternative embodiments. In some embodiments, for example, positive charges (holes) may be removed out from active region and collected by anode electrode, and negative charges (electrons) may be removed out from active region and collected by cathode electrode. Any other suitable V_{rb} generation technique may be used in alternative embodiments.

In various embodiments, Driver Circuit 108 and/or 210, and/or charge pump 502, may be implemented using suitable hardware, such as one or more Application-Specific Integrated Circuits (ASIC), using discrete components, or a combination of ASIC and discrete components.

Although the embodiments described herein mainly address turn-off techniques for VCSEL laser diodes, the methods and circuits described herein can also be used in other applications such as turn-off of other suitable laser diodes, and in light emitting diodes (LEDs).

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An optoelectronic device, comprising:
a laser diode having a first terminal and a second terminal;
a driver, which is coupled to drive current pulses through the laser diode between the first and second terminals; and
a reverse-bias circuit, configured to reverse-bias the laser diode during time intervals derived from the current pulses.

2. The device according to claim 1, wherein the laser diode comprises a vertical-cavity surface-emitting laser (VCSEL).

3. The device according to claim 1, wherein the reverse-bias circuit is configured to reverse-bias the laser diode at a first time-delay after start times of the current pulses, and to stop reverse-biasing the laser diode at a second time-delay after end times of the current pulses.

4. The device according to claim 1, wherein, by reverse-biasing the laser diode, the reverse-bias circuit is configured to set a fall time of 40 db of an emitted optical energy of the laser diode to less than 2 nano-seconds.

5. The device according to claim 1, wherein the driver comprises a unidirectional current source configured to generate the current pulses, and wherein the reverse-bias circuit comprises an additional power source configured to generate power for reverse-biasing the laser diode.

6. The device according to claim 5, wherein the additional power source comprises a charge-pump circuit.

7. The device according to claim 5, wherein the additional power source comprises a resistance, across which a voltage drop develops as a result of the current pulses.

8. The device according to claim 1, wherein the driver is configured to generate the current pulses from a first supply voltage, and wherein the reverse-bias circuit is configured to reverse-bias the laser diode using a second supply voltage, higher than the first supply voltage.

9. A method, comprising:
driving current pulses through a laser diode; and
reverse-biasing the laser diode during time intervals derived from the current pulses.

10. The method according to claim 9, wherein the laser diode comprises a vertical-cavity surface-emitting laser (VCSEL).

11. The method according to claim 9, wherein reverse-biasing the laser diode comprises starting reverse-biasing of the laser diode at a first time-delay after start times of the current pulses, and stopping reverse-biasing the laser diode at a second time-delay after end times of the current pulses.

12. The method according to claim 9, wherein reverse-biasing the laser diode comprises setting a fall time of 40 db of an emitted optical energy of the laser diode to less than 2 nano-seconds.

13. The method according to claim 9, wherein driving the current pulses comprises generating the current pulses by a unidirectional current source, and wherein reverse-biasing the laser diode comprises generating power for reverse-biasing the laser diode using an additional power source.

14. The method according to claim 13, wherein the additional power source comprises a charge-pump circuit.

15. The method according to claim 13, wherein the additional power source comprises a resistance, across which a voltage drop develops as a result of the current pulses.

16. The method according to claim 9, wherein driving the current pulses comprises generating the current pulses from a first supply voltage, and wherein reversing-biasing the laser diode comprises using a second supply voltage, higher than the first supply voltage.
